(19) United States
(12) Patent Application Publication
(10) Pub. No.: US 2007/0210865 A1
(43) Pub. Date: Sep. 13, 2007

(54) Method and apparatus for recharging portable electronic devices from audio sources

(76) Inventor: Thomas Christopher Giannulli, Simi Valley, CA (US)

Correspondence Address: Thomas C. Giannulli, 4838 Westwood St., Simi Valley, CA, 93063, US

(21) Appl. No.: 11/714,242

(22) Filed: Mar. 2, 2007

Related U.S. Application Data
(60) Provisional application No. 60/781,076, filed on Mar. 10, 2006.

(51) Int. Cl. H03F 3/68

(52) U.S. Cl. 330/125

(57) ABSTRACT

The invention is a power converter that coverts audio signal energy into a regulated DC power. The invention uses the audio output sources available on most modern transportation systems such as airplanes, trains and busses and converts the electrical output of those sources to an electrical output that can be used to recharge or allow extended use of various portable electronic devices. The main components of the invention include a rectifier section which is designed to rectify and amplify input AC signal energy. This is followed by a current storage section which accumulates the input energy and determines if the stored energy is sufficient to be output to the regulator component. The regulator component converts stored energy component signal into regulated DC output.

### BACKGROUND OF THE INVENTION

1. Technical Field

The object of the invention is to allow the continued use or recharging of portable electronic devices and more particularly the continued use or recharging of portable electronic devices by mean of electronic audio output sources.

2. Description of Related Art

Mobile devices are supposed to make life on the go easier, and for the most part they do. But no matter how small or lightweight a notebook, PDA, cell phone or other portable electronic device is, they still must have a power supply such as a battery or bulky AC adapter bricks to power the device and/or recharge batteries. Every year, engineers develop more-powerful microchips that enable devices to perform a greater number of functions. These devices are in turn used more frequently and often relied upon at all hours, and thus place a greater drain on battery life as power requirements outpace power supply.

As a result, sometimes the batteries of a portable electronic device will be dead or low and the user will be unable to find an electrical outlet to power the device and/or recharge the batteries. Often this situation occurs on modern transportation systems, including airplanes, trains and busses of which many now include audio outputs. What is needed is a device that can use the audio outputs of modern transportation systems as a power source to power handheld devices.

### SUMMARY

The present invention uses the audio output sources are available on most modern transportation systems such as airplanes, trains and busses and converts the electrical output of those sources to an electrical output that can be used to recharge or allow extended use of various portable electronic devices.

As shown in FIG. 1, connector 102 is inserted into audio output 104. Audio output 104 is a typically output found on most modern transportation systems. The electrical signal from audio output typically ranges from 1-3V p-p output. Connector 102 transmits the electrical signal from audio output 104 to rectifier 106, Step 204.

Rectifier 106 comprises one or more semi conductive devices, such as diodes or FETs, arranged for converting alternating current to continuous current and if the received signal is a stereo output, then each channel may be summed to form a maximum voltage, Step 206.

In one embodiment four diodes connected in bridge configuration may be used and such a configuration is a standard commercial component available with various voltage and current ratings. Use of the bridge configuration, or bridge rectifier, produces a full-wave rectification which converts both polarities of the signal from audio output 104 to DC.

Rectifier 106 transmits the rectified signal to capacitor 108 where it is stored, Step 208. Preferably, capacitor 108 is a large capacitor, known as a super-capacitor, or a rechargeable power cell/battery. A super capacitor in addition to a power cell/battery, in parallel configuration, is also considered as an alternate embodiment that provides supplemental power to the circuit in times of low audio input energy. The preferred embodiment uses a super-capacitor which allows for large charge capacities within a small package size. In the preferred embodiment, once the charge is stored the resultant charge level is compared to a standard reference voltage via a voltage reference integrated circuit or similar device.

Next it is determined if the super-capacitor voltage is above the preset voltage threshold, then the charge is sent to, a charge pump or voltage converter/regulator 110, Step 212 In other envisioned embodiments the capacitor 108 may be directly attached to a target mobile device bypassing the voltage conversion step discussed below.

Charge pump 110 is used to convert the voltage from the super-capacitor to a standard regulated voltage, Step 214. This regulated output voltage of the charge pump can be preset to a standard 5V or may be adjusted based on the electrical characteristics of the attached cable extension.

The regulated output is then sent to the output cable extension 112 which may represent a fixed or interchangeable cable extension, Step 216. The output regulated value may be fixed/preset or adjusted via various means including the electrical characteristics of the attached extension cable and such adjustments are known to those skilled in the art.

It should be understood that the foregoing relates to exemplary embodiments of the invention and that modifications may be made without departing from the spirit and scope of the invention.

### BRIEF DESCRIPTION OF THE DRAWINGS

The above and other features and advantages of this invention will be more readily apparent from a reading of the following detailed description of various aspects of the invention taken in conjunction with the accompanying drawings, in which:

FIG. 1 is block diagram of the components used in the present invention.

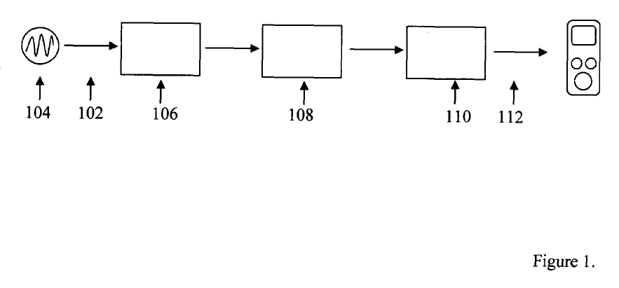

FIG. 2 is a flow diagram depicting the step used in the present invention.

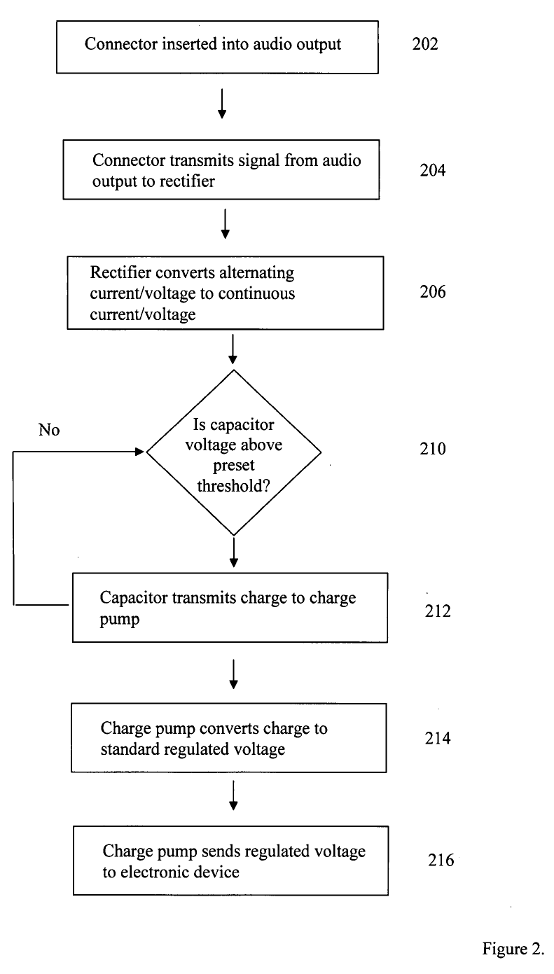

What is claimed is:

1. A device that converts the electrical output signal from an audio output source to an electrical output that can be used as a means of power supply by portable electronic devices.

2. The device of claim 1 wherein the audio output is an audio output typically output found on most modern transportation systems.

3. The device of claim 1 wherein the electrical energy of the audio output source of claim 2 may be accumulated via a rechargeable energy cell or capacitor.

4. The device of claim 1 wherein the energy cell of claim 3 may be supplemented by an additional energy cell.

5. The device of claim 1 wherein the energy cell of claim 3 may be converted and regulated to a desired output voltage.

6. The device of claim 1 wherein the converted output voltage of claim 4 may be determined by the electrical characteristics of an attachment part.
